(19) United States
(12) Patent Application Publication
(10) Pub. No.: US 2012/0200365 A1
(43) Pub. Date: Aug. 9, 2012

(54) METHOD OF MANUFACTURING PIEZOELECTRIC VIBRATING REED, PIEZOELECTRIC VIBRATING REED, PIEZOELECTRIC VIBRATOR, OSCILLATOR, ELECTRONIC APPARATUS, AND RADIO TIMEPIECE

(76) Inventor: Daiki Irokawa, Chiba-shi (JP)

(21) Appl. No.: 13/361,092

(22) Filed: Jan. 30, 2012

(30) Foreign Application Priority Data
Feb. 7, 2011 (JP) 2011-024239

(51) Int. Cl. H01L 41/04; H05K 3/02; H03B 5/32; H01L 41/22

(52) U.S. Cl. 331/155; 29/25.35; 310/370; 310/344

(57) ABSTRACT

A photoresist film forming process is performed by the use of a forming apparatus that has a sprayer which generates an air flow toward metal film on a wafer to spray the photoresist material, and a plurality of spacers which is disposed between a work stage and the wafer.

### RELATED APPLICATIONS

This application claims priority under 35 U.S.C. §119 to Japanese Patent Application No. 2011-024239 filed on Feb. 7, 2011, the entire content of which is hereby incorporated by reference.

### BACKGROUND OF THE INVENTION

1. Field of the Invention

The present invention relates to a method of manufacturing a piezoelectric vibrating reed, a piezoelectric vibrating reed, a piezoelectric vibrator, an oscillator, an electronic apparatus, and a radio timepiece.

2. Description of the Related Art

For example, in a mobile phone or a personal digital assistant, in many cases, a piezoelectric vibrator is used which uses crystal or the like as a time source, a timing source such as a control signal, a reference signal source or the like. As the piezoelectric vibrator of this kind, there is a vibrator in which a tuning fork-like piezoelectric vibrating reed is sealed in a package formed with a cavity in an air-tight manner.

The piezoelectric vibrating reed includes a piezoelectric plate which has a pair of vibration arm portions that is extended in a longitudinal direction and is disposed so as to be lined up side by side in a width direction, and a base portion that connects proximal end sides of both vibration arm portions to each other; a pair of excitation electrodes that is formed in the respective vibration arm portions; and mount electrodes that are formed in the base portion and are electrically connected to the pair of excitation electrodes, respectively. Moreover, a configuration is provided in which the voltage is applied to the respective excitation electrodes from the outside, whereby both vibration arm portions are vibrated (oscillated) at a predetermined resonance frequency in a direction of approaching or being separated from each other by using the proximal end side to a starting point.

As a method of forming the respective electrodes (the excitation electrode, the mount electrode or the like) on the piezoelectric plate mentioned above, methods as below are known.

Firstly, a metal film is formed on a wafer forming the piezoelectric plate by the use of the sputtering or the like. Then, a photoresist material is applied onto the metal film to form a photoresist film. Next, the photoresist film is patterned by a photolithography technique, and a mask for forming each electrode is formed. Finally, by etching the metal film via the mask, the metal film is patterned to form each electrode.

However, in a case where the application of the photoresist material is performed by a spray coat method, for example, the photoresist material being sprayed toward the wafer by the use of a sprayer is considered.

However, in the case of applying the photoresist material by the spray coat method, it is difficult to sufficiently apply the photoresist material due to the surface tension of the photoresist material in corners of the piezoelectric plate, whereby a region is generated in which the photoresist film is thin or the photoresist film is not formed. In this region, the mask is insufficient when forming the electrodes, and there is a fear that the metal film of the corners of the piezoelectric plate may be etched when etching the metal film. As a consequence, there is a problem in that the electrodes in the corner may be disconnected, whereby a CI (Crystal Impedance) value is degraded.

Thus, for example, JP-A-2007-295555 describes a configuration which makes it easy to apply the photoresist material on the metal film of an edge portion by forming the step portion in the edge portion of the piezoelectric plate.

However, in the configuration of JP-A-2007-295555, there is a problem in that, there is a need to form a step portion in a separate process after forming the exterior of the piezoelectric plate, which leads to an increase in the number of manufacturing processes, and a decline in manufacturing efficiency.

Furthermore, there is a problem in that the exterior is changed from the piezoelectric reed of the related art, whereby the vibration characteristics fluctuate.

Thus, the present invention was made in view of the above problems, and an object thereof is to provide a method of manufacturing a piezoelectric vibrating reed which can evenly form a coating film pattern on the piezoelectric plate by suppressing an increase in the number of manufacturing processes, a decline in manufacturing efficiency, and a fluctuation in vibration characteristics, a piezoelectric vibrating reed, a piezoelectric vibrator, an oscillator, an electronic apparatus, and a radio timepiece.

### SUMMARY OF THE INVENTION

In order to solve the problems mentioned above, the present invention provides means as below.

According to the present invention, there is provided a method of manufacturing the piezoelectric vibrating reed which has a mask forming process of applying a mask material to a coating film formed on a piezoelectric plate to form a mask on the coating film; a mask pattern forming process of patterning the mask to form a mask pattern; and a coating film pattern forming process of removing the coating film of a region other than a forming region of the mask pattern to form the coating film pattern, wherein the mask forming process is performed by the use of a mask forming apparatus that has a sprayer which generates an air flow toward the coating film to spray the mask material, and ventilation means for distributing the air flow to a side opposite to the sprayer with respect to the piezoelectric plate.

According to the configuration, by distributing the air flow generated by the sprayer to the side opposite to the sprayer with respect to the piezoelectric plate, it is possible to improve the air permeability of the piezoelectric plate in a thickness direction. That is, the air flow to be generated by the sprayer passes through the piezoelectric plate, whereby the mask material applied onto the coating film is easily dried. In this case, since the mask material is gradually deposited on the dried mask material, the surface tension of the mask material in the corner of the piezoelectric plate can be reduced, whereby it is easy to apply the mask material to the corner of the piezoelectric plate. Thus, it is possible to evenly form the mask over the whole surfaces of the piezoelectric plate.

As a result, since the mask pattern can be evenly formed in the forming region of the coating film pattern, the forming region of the coating film pattern is not removed in the coating film pattern forming process. As a consequence, it is possible to evenly form the coating film pattern on the piezoelectric plate.

In this case, since the air flow is merely distributed to a side opposite to the sprayer with respect to the piezoelectric plate by the ventilation means, it is possible to suppress an increase in the number of manufacturing process and a decline in manufacturing efficiency.

Additionally, since the exterior of the piezoelectric plate is not changed, the vibration characteristics do not fluctuate.

Furthermore, in the mask forming process, the spraying by the sprayer may be performed in the state of setting the piezoelectric plate on a work stage disposed at a side opposite to the sprayer with respect to the piezoelectric plate, and the ventilation means is a spacer that is disposed between the piezoelectric plate and the work stage.

According to the configuration, after the air flow passing through the piezoelectric plate reaches the work stage, the air flow is distributed through a gap formed between the piezoelectric plate and the work stage by the spacer. As a result, it is possible to reliably improve the air permeability of the piezoelectric plate in the thickness direction.

Additionally, in the mask forming process, the spraying by the sprayer may be performed in the state of setting the piezoelectric plate on the work stage disposed at a side opposite to the sprayer with respect to the piezoelectric plate, and the ventilation means is a vent hole that is formed so as not to overlap the piezoelectric plate in a thickness direction in the work stage.

According to the configuration, after the air flow passing through the piezoelectric plate reaches the work stage, the air flow passes through the work stage via the vent hole. As a result, it is possible to reliably improve the air permeability of the piezoelectric plate in the thickness direction.

Furthermore, the coating film may be a conductive metal film becomes an electrode formed on the piezoelectric plate, and the mask material is a photoresist material that becomes a mask when forming the electrode.

According to the configuration, since the forming region of the electrode is not removed in the coating film forming process, it is possible to evenly form the electrode on the piezoelectric plate. As a result, the disconnection of the electrode is prevented, whereby it is possible to provide a piezoelectric vibrating reed which has no conduction defects, has a low CI value, and has high quality.

Additionally, according to the present invention, there is provided a piezoelectric vibrating reed which is manufactured by the use of the method of manufacturing the piezoelectric vibrating reed of the present invention.

According to the configuration, since the piezoelectric vibrating reed is manufactured by the use of the method of manufacturing the piezoelectric vibrating reed of the present invention, it is possible to provide a piezoelectric vibrating reed of high quality.

Furthermore, according to the present invention, there is provided a piezoelectric vibrator which is configured so that the piezoelectric vibrating reed of the present invention is sealed in a package in an air-tight manner.

According to the configuration, since the piezoelectric vibrating reed is sealed in the package in the air-tight manner, it is possible to provide a piezoelectric vibrator of high quality having excellent characteristics and reliability.

Furthermore, according to the present invention, there is provided an oscillator which is configured so that the piezoelectric vibrator of the present invention is electrically connected to an integrated circuit as an oscillating element.

Furthermore, according to electronic apparatus the present invention, there is provided an electronic apparatus which is configured so that the piezoelectric vibrator of the present invention is electrically connected to a clock portion.

Furthermore, according to the present invention, there is provided a radio timepiece which is configured so that the piezoelectric vibrator of the present invention is electrically connected to a filter portion.

With the oscillator, the electronic apparatus, and the radio timepiece according to the present invention, it is possible to provide the oscillator, the electronic apparatus, and the radio timepiece of high quality having excellent characteristics and reliability.

According to the method of manufacturing the piezoelectric vibrating reed and the piezoelectric vibrating reed of the present invention, it is possible to evenly form the coating film pattern on the piezoelectric plate, by suppressing an increase in the number manufacturing processes, a decline in manufacturing efficiency, and fluctuation in vibration characteristics.

According to the piezoelectric vibrator of the present invention, it is possible to provide the piezoelectric vibrator of high quality having excellent characteristics and reliability.

With the oscillator, the electronic apparatus, and the radio timepiece of the present invention, it is possible to provide the oscillator, the electronic apparatus, and the radio timepiece of high quality having excellent characteristics and reliability.

### BRIEF DESCRIPTION OF THE DRAWINGS

FIG. 1 is an exterior perspective view that shows a piezoelectric vibrator according to an embodiment of the present invention.

FIG. 2 is a plan view that shows an internal configuration of the piezoelectric vibrator shown in FIG. 1 with a lead substrate detached therefrom.

FIG. 3 is a cross-sectional view taken along the lines A-A of FIG. 2.

FIG. 4 is an exploded perspective view of the piezoelectric vibrator shown in FIG. 1.

FIG. 5 is a plan view of the piezoelectric vibrating reed.

FIG. 6 is a bottom view of the piezoelectric vibrating reed.

FIG. 7 is a cross-sectional view taken from lines B-B of FIG. 5.

FIG. 8 is a flowchart that shows a method of manufacturing the piezoelectric vibrator.

FIG. 9 is a flowchart that shows a method of manufacturing the piezoelectric vibrating reed.

FIG. 10 is an exploded perspective view of a wafer bonding body.

FIG. 11 is a plan view of the wafer that shows the state patterning an exterior pattern to the exterior shape of the piezoelectric plate.

FIG. 12 is a plan view of the wafer that shows the state patterning the wafer to the exterior shape of the piezoelectric plate.

FIG. 13 is a plan view of the wafer for describing a photoresist film forming process.

FIG. 14 is a cross-sectional view corresponding to lines C-C of FIG. 12 for describing the photoresist film forming process.

FIG. 15 is a schematic configuration diagram of an oscillator in an embodiment of the present invention.

FIG. 16 is a schematic configuration diagram of a portable information device in the embodiment of the present invention.

FIG. 17 is a schematic configuration diagram of a radio timepiece in the embodiment of the present invention.

### DETAILED DESCRIPTION OF THE PREFERRED EMBODIMENTS

Hereinafter, an embodiment of the present invention will be described based on the drawings.

### (Piezoelectric Vibrator)

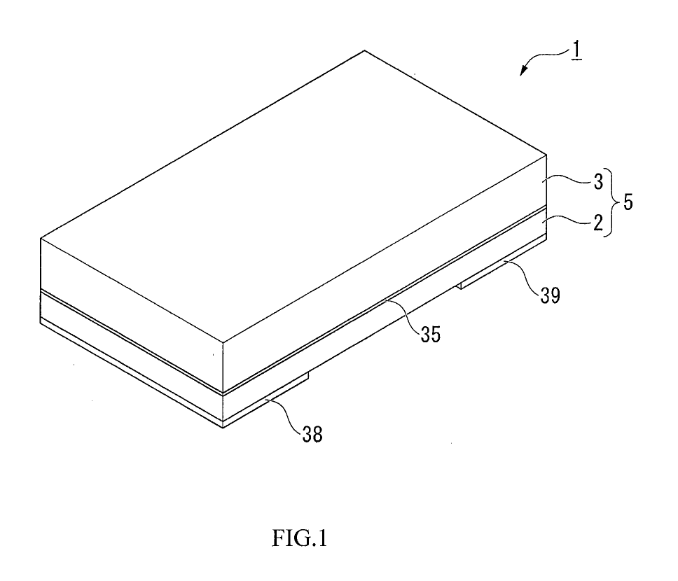

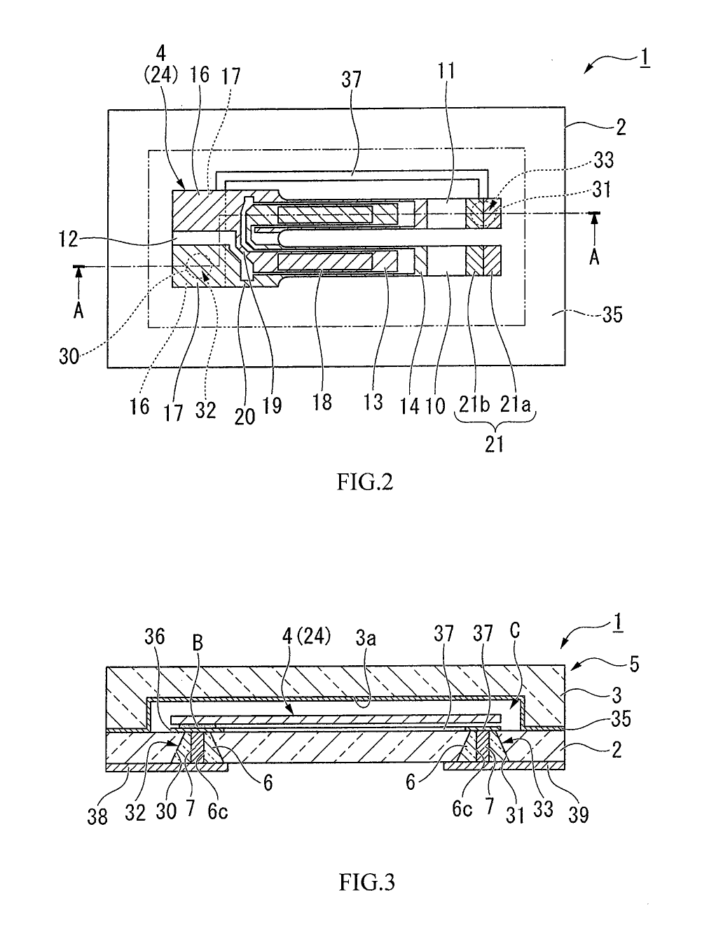

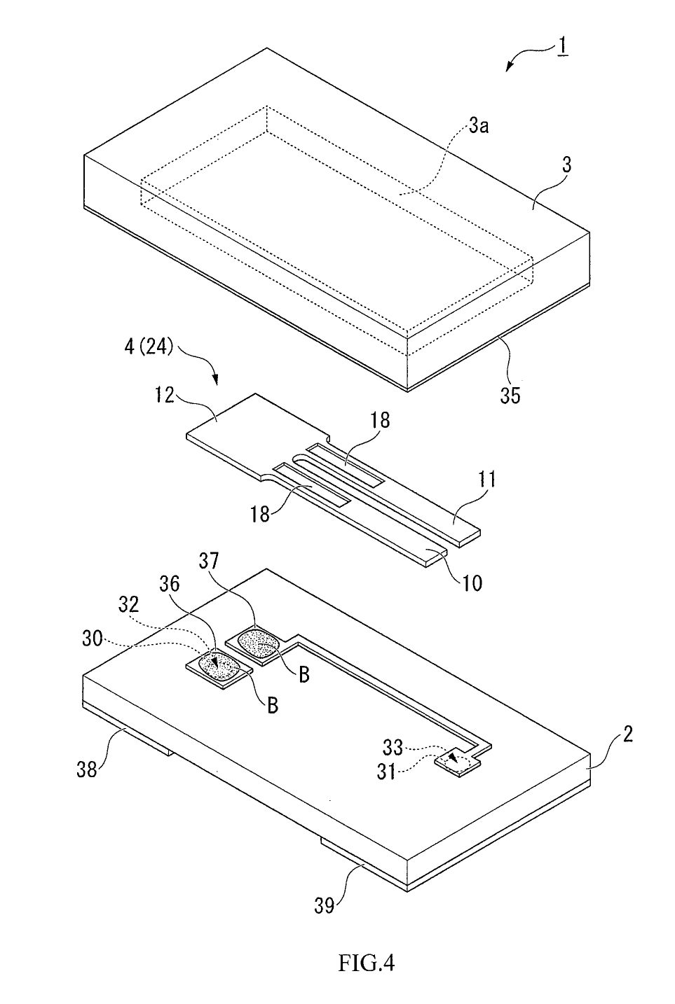

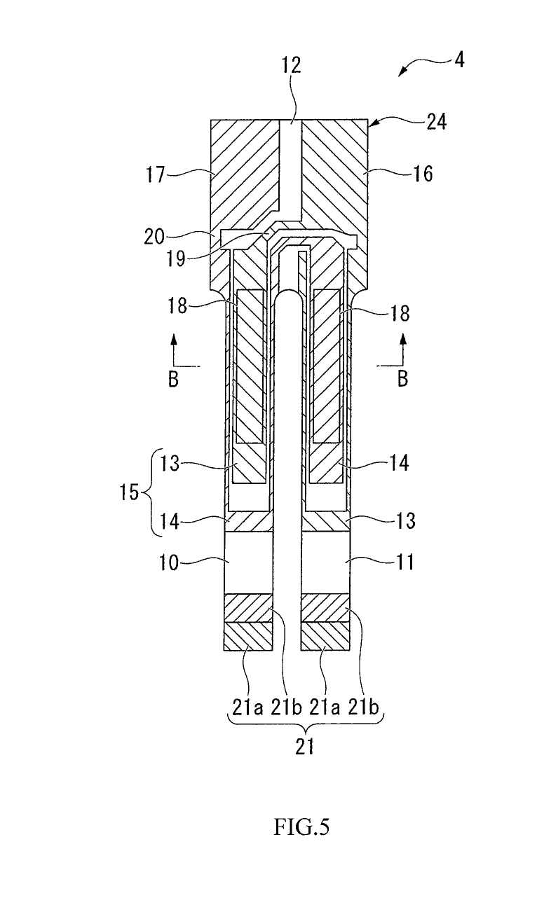

FIG. 1 is an exterior perspective view in which a piezoelectric vibrator in the present embodiment is viewed from a lead substrate side. Furthermore, FIG. 2 is an internal configuration diagram of the piezoelectric vibrator in which the piezoelectric vibrating reed is viewed from the upper part with the lead substrate detached therefrom. Furthermore, FIG. 3 is a cross-sectional view of the piezoelectric vibrator taken along lines A-A shown in FIG. 2, and FIG. 4 is an exploded perspective view of the piezoelectric vibrator.

As shown in FIGS. 1 to 4, a piezoelectric vibrator 1 of the present embodiment is a surface mount type piezoelectric vibrator which has a box-shaped package 5 in which a base substrate 2 and a lead substrate 3 are anodically bonded to each other via a bonding material 35, and has a piezoelectric vibrating reed 4 that is sealed in a cavity C in an inner portion of the package 5. In addition, in FIG. 4, in order to clarify the drawings, an excitation electrode 15, drawing electrodes 19 and 20, mount electrodes 16 and 17, and a weight metal film 21 are not shown.

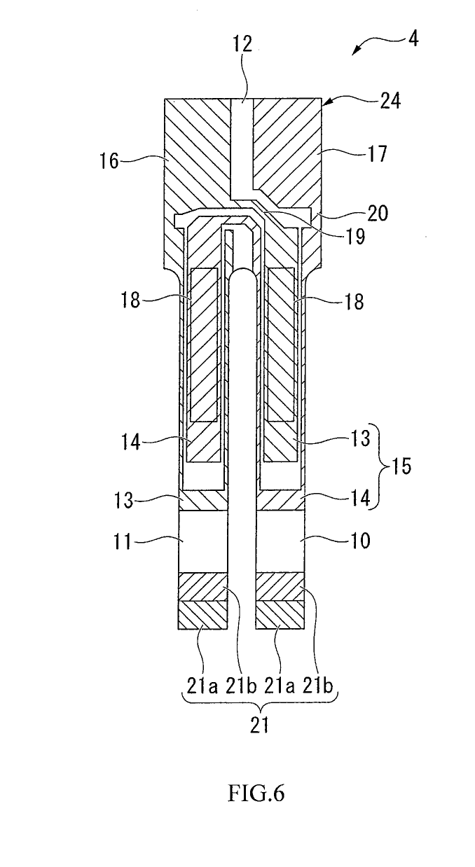

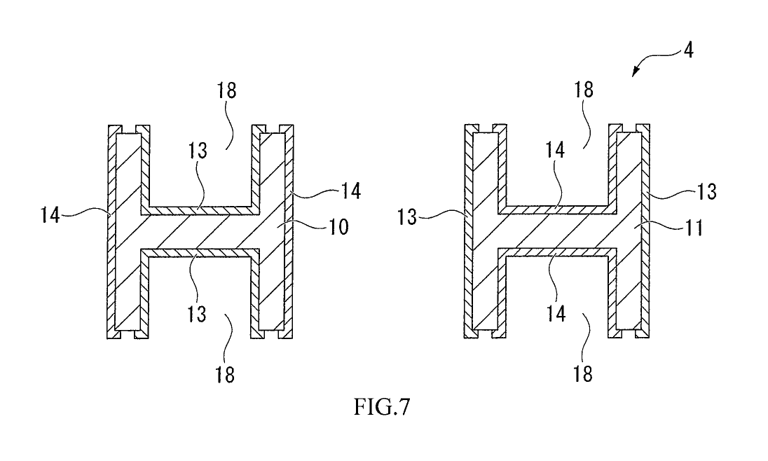

FIG. 5 is a top view of the piezoelectric vibrating reed 4 constituting the piezoelectric vibrator 1. FIG. 6 is a bottom view of the piezoelectric vibrating reed 4, and FIG. 7 is a cross-sectional view taken along lines B-B of FIG. 5.

As shown in FIGS. 5 to 7, the piezoelectric vibrating reed 4 is vibrated when a predetermined voltage is applied, and includes a tuning fork-shaped piezoelectric plate 24 formed of a piezoelectric material such as crystal, lithium tantalite, and lithium niobate.

The piezoelectric plate 24 has a pair of vibration arm portions 10 and 11 disposed in parallel, and a base portion 12 that integrally fixes a proximal end side of the pair of vibration arm portions 10 and 11. Furthermore, on an outer surface of the piezoelectric plate 24, there are provided an excitation electrode 15 that is constituted by a first excitation electrode 13, which vibrates the pair of vibration arm portions 10 and 11, and a second excitation electrode 14, and mount electrodes 16 and 17, which are electrically connected to the first excitation electrode 13 and the second excitation electrode 14.

Furthermore, in the piezoelectric plate 24, on both main surfaces of the pair of vibration arm portions 10 and 11, groove portions 18, which are formed along a longitudinal direction of the vibration arm portions 10 and 11, respectively, are formed. The groove portions 18 are formed so as to reach a portion near approximately the middle from the proximal end sides of the vibration arm portions 10 and 11.

The excitation electrode 15 including the first excitation electrode 13 and the second excitation electrode 14 is an electrode that vibrates the pair of vibration arm portions 10 and 11 in a direction approaching or separated from each other at a predetermined frequency, and is patterned and formed on the outer surfaces of the pair of vibration arm portions 10 and 11 in the state of being electrically separated, respectively.

Specifically, on the groove portions 18 of one vibration arm portions 10 and on both side surfaces of the other vibration arm portions 11, the first excitation electrode 13 is mainly formed. Furthermore, on both side surfaces of one vibration arm portion 10 and the groove portion 18 of the other vibration arm portion 11, the second excitation electrode 14 is mainly formed.

In addition, the first excitation electrode 13 and the second excitation electrode 14 are electrically connected to the mount electrodes 16 and 17 via the drawing electrodes 19 and 20 on both main surfaces of the base portion 12, respectively. The piezoelectric vibrating reed 4 is applied with the voltage via the mount electrodes 16 and 17.

Furthermore, the outer surfaces of the pair of vibration arm portions 10 and 11 are coated with a frequency adjusting weight metal film 21 so that the vibration state thereof is vibrated in a predetermined frequency range. The weight metal film 21 is formed of, for example, silver (Ag) or gold (Au), and is divided into a rough adjustment film 21a that is used when roughly adjusting the frequency, and a minute adjustment film 21b used when minutely adjusting the frequency. By performing the frequency adjustment by the use of the weights of the rough adjustment film 21a and the minute adjustment film 21b, it is possible to put the frequencies of the pair of vibration arm portions 10 and 11 within an objective frequency of the device.

As shown in FIGS. 3 and 4, the piezoelectric vibrating reed 4 configured in this manner is bump-bonded to an upper surface of the base substrate 2 by the use of a bump B such as gold. More specifically, on two bumps B formed on leading electrodes 36 and 37 described below patterned on the upper surface of the base substrate 2, the pair of mount electrodes 16 and 17 is bump-bonded in the state of contact state, respectively.

As a result, the piezoelectric vibrating reed 4 is supported in the state of floating from the upper surface of the base substrate 2, and the mount electrodes 16 and 17 and the leading electrodes 36 and 37 are electrically connected to each other, respectively.

As shown in FIGS. 1, 3, and 4, the lead substrate 3 is a transparent insulation substrate formed of a glass material, for example, a soda-lime glass, and is formed in a plate shape. At the bonding surface side bonded with the base substrate 2, a rectangular concave portion 3a is formed into which the piezoelectric vibrating reed 4 enters. The concave portion 3a is a concave portion for the cavity becoming the cavity C that accommodates the piezoelectric vibrating reed 4 when both of the substrates 2 and 3 overlap with each other.

On the whole lower surface of the lead substrate 3, a bonding material 35 for the anodic bonding is formed. Specifically, the bonding material 35 is formed all over the bonding surface with the base substrate 2 and all over the inner surface of the concave portion 3a. The bonding material 35 of the present embodiment is formed by Si film, but the bonding material 35 is also able to be formed of Al. Furthermore, it is also possible to adopt a Si bulk material having low resistance by the doping or the like, as the bonding material. Furthermore, the bonding material 35 and the base substrate 2 are anodically bonded to each other in the state of causing the concave portion 3a to face the base substrate 2 side, whereby the cavity C is sealed in an air-tight manner.

As shown in FIGS. 1 to 4, the base substrate 2 is a transparent insulation substrate formed of a glass material like the lead substrate 3, for example, a soda-lime glass, and is formed in a plate shape having a size that can overlap the lead substrate 3. The base substrate 2 is formed with a pair of through holes 30 and 31 that penetrates the base substrate 2. At this time, the pair of through holes 30 and 31 is formed so as to enter the cavity C.

More specifically, among the through holes 30 and 31 of the present embodiment, one through hole 30 is formed at a position corresponding to the base portion 12 side of the mounted piezoelectric vibrating reed 4. Furthermore, the other through hole 31 is formed at a position corresponding to the tip ends of the vibration arm portions 10 and 11. Furthermore, the through holes 30 and 31 are formed in a taper-shaped cross section in which the diameters thereof are gradually reduced from the lower surface of the base substrate 2 toward the upper surface.

In addition, in the present embodiment, a case was described where the respective through holes 30 and 31 are formed in the taper-shaped cross section, but a through hole may be adopted which directly penetrates the base substrate 2, without being limited thereto. In any case, the through hole may penetrate the base substrate 2.

Moreover, the pair of through holes 30 and 31 is formed with a pair of penetration electrodes 32 and 33 that is formed so as to bury the respective through holes 30 and 31.

As shown in FIG. 3, the penetration electrodes 32 and 33 are formed by a barrel 6 integrally fixed to the through holes 30 and 31 by burning, and a core portion 7. The respective penetration electrodes 32 and 33 play a role in completely blocking the through holes 30 and 31 to maintain the air-tightness in the cavity C and conducting external electrodes 38 and 39 described later and the leading electrodes 36 and 37.

The barrel 6 is burned by a paste-like glass flit. The barrel 6 has flat both ends and is formed in a cylindrical shape having approximately the same thickness as the base substrate 2. Moreover, in the center of the barrel 6, the core portion 7 is disposed so as to penetrate the barrel 6. Additionally, in the present embodiment, according to the shapes of the through holes 30 and 31, the exterior of the barrel 6 is formed in a conical shape (taper-shaped cross section). Moreover, the barrel 6 is burned in the state of being buried in the through holes 30 and 31, whereby the barrel 6 is firmly fixed to the through holes 30 and 31.

The core portion 7 is a conductive core formed in a columnar shape by a metallic material, has flat both ends like the barrel 6, and is formed so as to have approximately the same thickness as that of the base substrate 2.

In addition, as shown in FIG. 3, when the penetration electrodes 32 and 33 are formed as finished products, the core portion 7 is formed so as to have approximately the same thickness as that of the base substrate 2. However, in the manufacturing course, as the length of the core portion 7, a length is adopted which is set to be shorter than the thickness of the initial base substrate 2 of the manufacturing course by 0.02 mm. Moreover, the core portion 7 is situated in the center hole 6c of the barrel 6, whereby the core portion 7 is firmly fixed to the barrel 6 by the burning of the barrel 6.

Furthermore, in the penetration electrodes 32 and 33, the electrical conductivity is ensured through the conductive core portion 7.

As shown in FIGS. 1 to 4, at the upper surface side (the bonding surface side with the lead substrate 3 bonded thereto) of the base substrate 2, the pair of leading electrodes 36 and 37 is patterned by a conductive material (for example, aluminum). The pair of leading electrodes 36 and 37 is patterned so as to electrically connect one penetration electrode 32 with one mount electrode 16 of the piezoelectric vibrating reed 4 and electrically connect the other penetration electrode 33 and the other mount electrode 17 of the piezoelectric vibrating reed 4, among the pair of penetration electrodes 32 and 33. More specifically, one leading electrode 36 is formed immediately over the penetration electrode 32 so as to be situated immediately under the base portion 12 of the piezoelectric vibrating reed 4. Furthermore, the other leading electrode 37 is formed so as to be situated immediately over the other penetration electrode 33 after being drawn from a position adjacent to one leading electrode 36 to the tip sides of the vibration arm portions 10 and 11 along the vibration arm portions 10 and 11.

Moreover, the bumps B are formed on the pair of leading electrodes 36 and 37, respectively, and the piezoelectric vibrating reed 4 is mounted by the use of the bumps B. As a result, one mount electrode 16 of the piezoelectric vibrating reed 4 is conducted to one penetration electrode 32 via one leading electrode 36. Additionally, the other mount electrode 17 is conducted to the other penetration electrode 33 via the other leading electrode 37.

As shown in FIGS. 1, 3, and 4, on the lower surface of the base substrate 2, external electrodes 38 and 39 electrically connected to the pair of penetration electrodes 32 and 33 are formed. That is, one external electrode 38 is electrically connected to the first excitation electrode 13 of the piezoelectric vibrating reed 4 via one penetration electrode 32 and one leading electrode 36.

Furthermore, the other external electrode 39 is electrically connected to the second excitation electrode 14 of the piezoelectric vibrating reed 4 via the other penetration electrode 33 and the other leading electrode 37.

In the case of operating the piezoelectric vibrator 1 configured in this manner, a predetermined driving voltage is applied to the external electrodes 38 and 39 formed in the base substrate 2. As a result, it is possible to cause the electric current to flow in the excitation electrode 15 including the first excitation electrode 13 and the second excitation electrode 14 of the piezoelectric vibrating reed 4, whereby the pair of vibration arm portions 10 and 11 can be vibrated in a direction approaching and separated from each other at a predetermined frequency. Moreover, the vibration of the pair of vibration arm portions 10 and 11 can be used as a timing source of the control signal, a reference signal source or the like.

### (Method of Manufacturing Piezoelectric Vibrator)

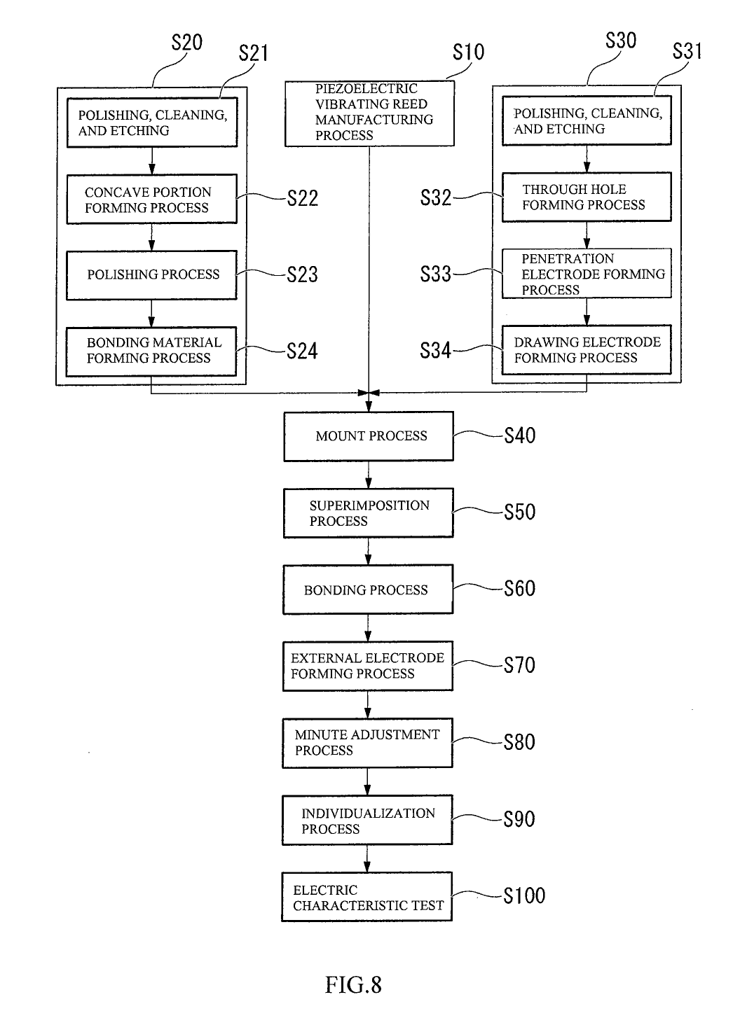

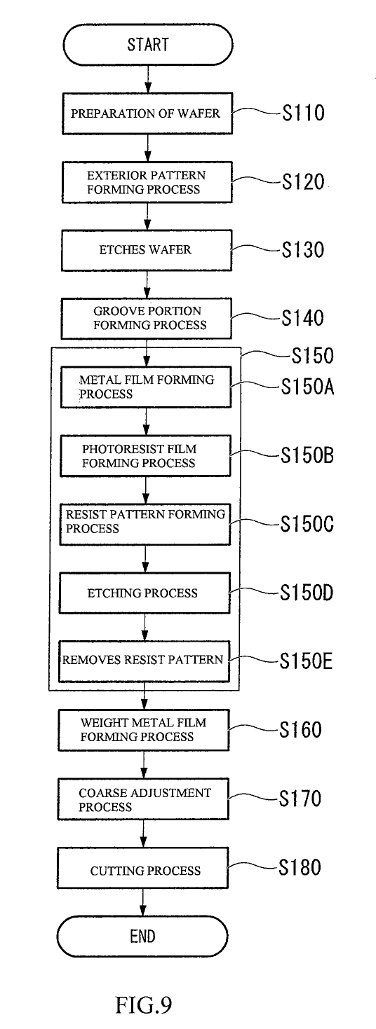

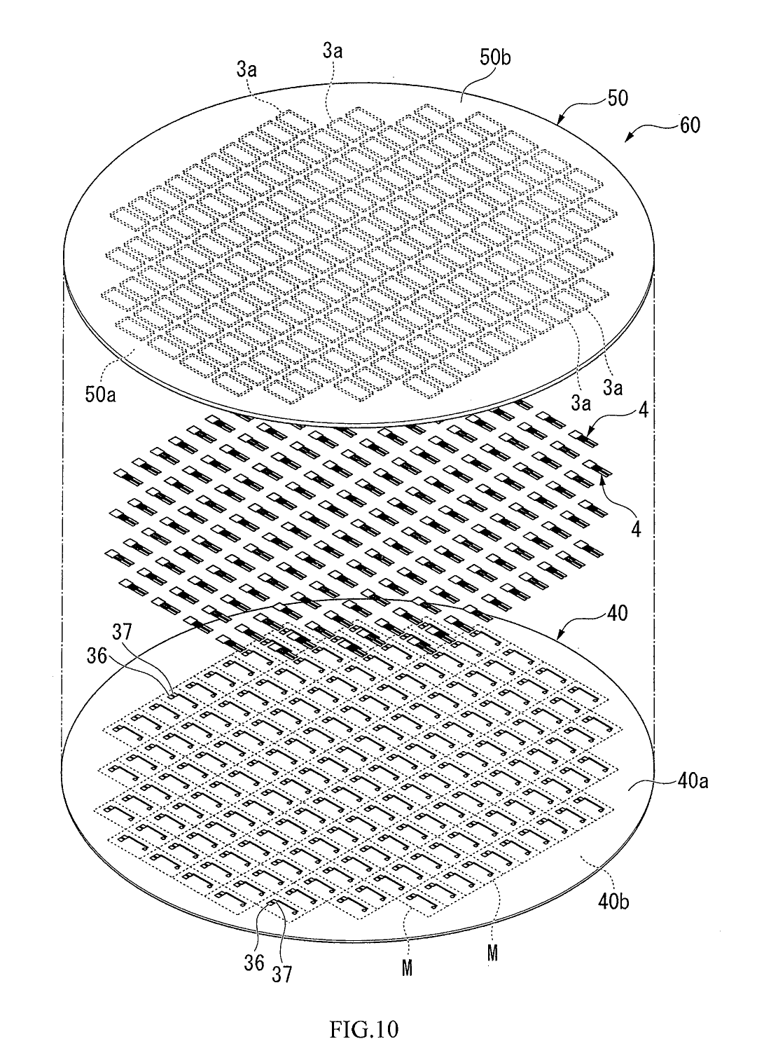

Next, a method of manufacturing the piezoelectric vibrator 1 mentioned above will be described. FIG. 8 is a flowchart that shows a method of manufacturing the piezoelectric vibrator, FIG. 9 is a flowchart that shows a piezoelectric vibrating reed production process, and FIG. 10 is an exploded perspective view of a wafer bonding body.

As shown in FIGS. 8 and 10, in the method of manufacturing the piezoelectric vibrator 1, a method will be described by which a plurality of piezoelectric vibrating reeds 4 is sealed between the base substrate wafer 40 with the plurality of base substrates 2 extended thereon and the lead substrate wafer 50 with the plurality of lead substrates 3 extended thereon to form a wafer bonding body 60, and a plurality of piezoelectric vibrators 1 is concurrently manufactured by cutting the wafer bonding body 60. In addition, a dashed-line M shown in FIG. 10 shows a cutting line that is cut in the cutting process.

The method of manufacturing the piezoelectric vibrator 1 in the present embodiment mainly has a piezoelectric vibrating reed production process (S10), a lead substrate wafer production process (S20), a base substrate wafer production process (S30), and an assembling process (S40 and below). Among them, it is possible to perform the piezoelectric vibrating reed production process (S10), the lead substrate wafer production process (S20), and the base substrate wafer production process (S30) in parallel.

### (Piezoelectric Vibrating Reed Production Process)

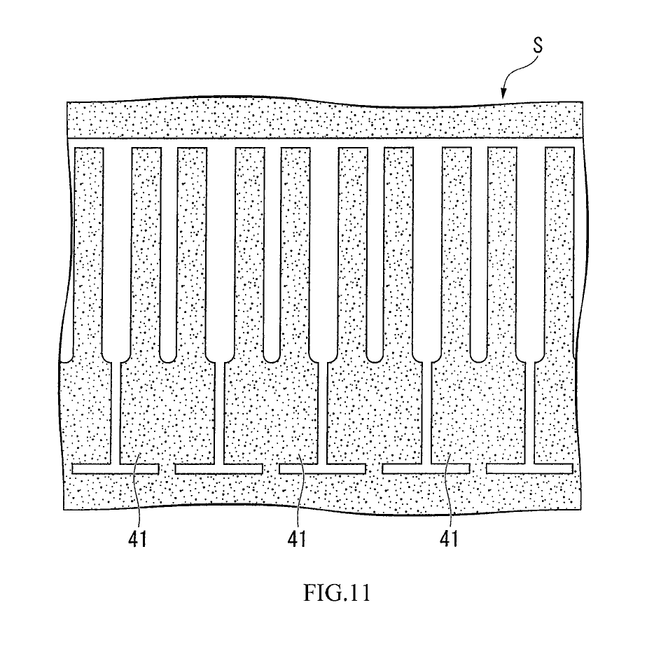

Firstly, as shown in FIGS. 8 and 9, the piezoelectric vibrating reed production process (S10) is performed to produce the piezoelectric vibrating reed 4 (see FIGS. 5 and 6). Specifically, a Lambert ore of crystal is sliced at a predetermined angle to form a wafer S (see FIG. 11) of a predetermined thickness. Next, after the wafer S is wrapped and roughed, a damaged layer is removed by the etching, and then the wafer S is formed to have a predetermined thickness by performing a specular working such as polishing (S110).

FIG. 11 is a diagram that shows the state of patterning the exterior pattern to an exterior shape of the piezoelectric plate.

Next, as shown in FIG. 11, an exterior pattern 41 for patterning the exterior shapes of the plurality of piezoelectric plates 24 is formed (S120). Specifically, the exterior pattern 41 is formed by forming the metal film formed of chrome (Cr) or the like on both sides of the wafer S and patterning the metal film so as to be modeled after the exterior shapes of the pair of vibration arm portions 10 and 11 and the base portion 12. At this time, the patterning is collectively performed by the number of the plurality of the piezoelectric vibrating reeds 4 formed on the wafer S.

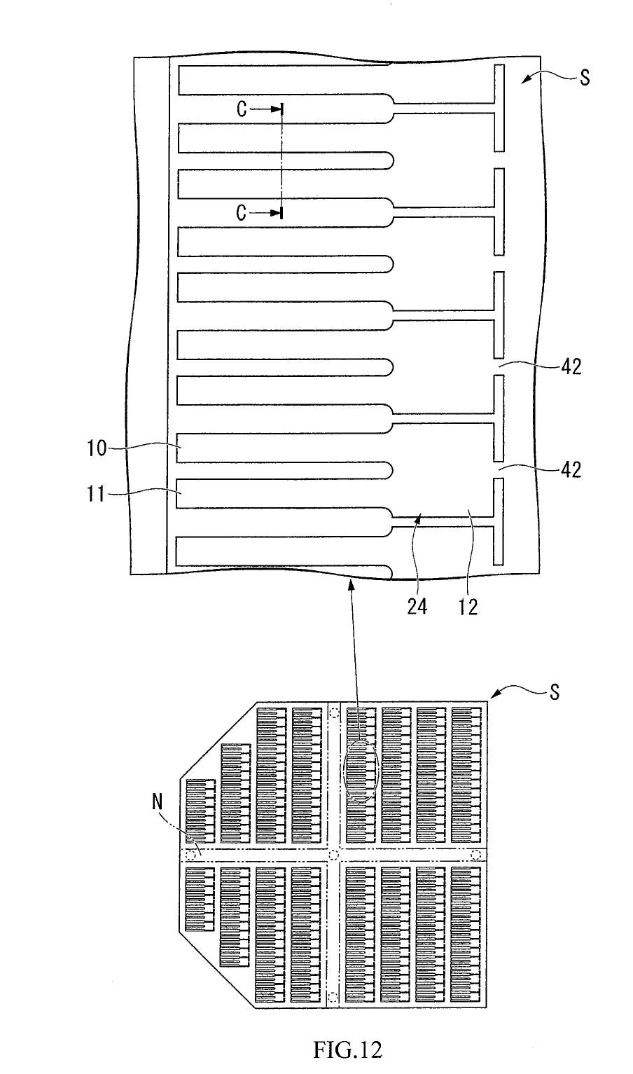

FIG. 12 is a plan view of the wafer that shows the state of patterning the wafer to the exterior shape of the piezoelectric plate.

Next, as shown in FIG. 12, the etching working is performed from both sides of the water S, respectively by setting the patterned exterior pattern 41 as the mask (S130). As a result, a region is selectively removed which is not masked by the exterior pattern 41. As a consequence, the wafer S patterned via the exterior pattern 41 is formed in an outer shape of the plurality of piezoelectric plates 24 having the pair of vibration arm portions 10 and 11 and the base portion 12. In addition, the plurality of piezoelectric plates 24 is connected to the wafer S via the connection portion 42 until a cutting process (S 180) performed later is performed. Additionally, in order to ensure the stiffness of the wafer S, the wafer S is provided with a non-formation region N in which the piezoelectric plate 24 is not formed in a cross shape including a center portion.

Next, a groove portion forming process is formed in which groove portions 18 are formed on both main surfaces in the pair of vibration arm portions 10 and 11 in the respective piezoelectric plates 24 (S140). Specifically, the exterior pattern 41 mentioned above is patterned again so as to be opened by the forming region of the groove portion 18. Moreover, the etching working is performed by using the patterned exterior pattern 41 as the mask. As a result, the region not masked by the exterior pattern 41 is selectively removed, whereby it is possible to form the groove portions 18 on both main surfaces of the pair of vibration arm portions 10 and 11, respectively. After that, the masked exterior pattern 41 is removed. In addition, FIG. 11 shows the state in which the groove portion 18 is formed in advance and the exterior pattern 41 is removed, and in order to clarify the drawings, the groove portion 18 and the exterior pattern 41 are omitted.

### (Electrode Forming Process)

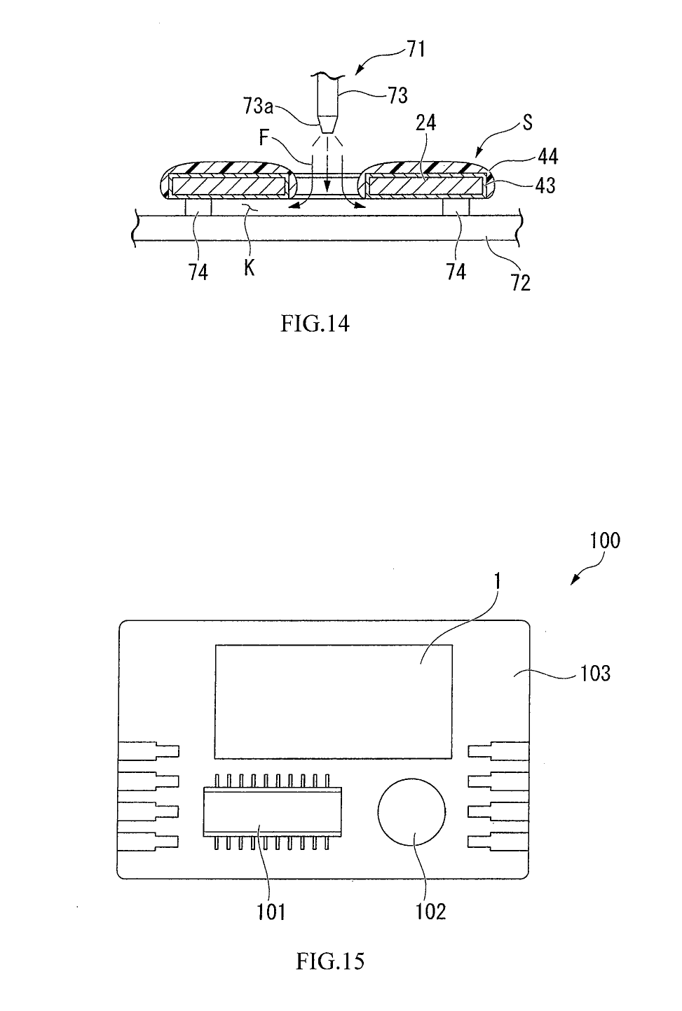

Next, an electrode forming process is performed in which the excitation electrodes 13 and 14, the drawing electrodes 19 and 20, and the mount electrodes 16 and 17 are formed on the outer surfaces of the plurality of piezoelectric plate 24 (S150). Specifically, a metal film (a coating film) 43 (see FIG. 14) having conductivity is formed on the outer surface of the piezoelectric plate 24 by the vapor deposition method, the sputtering method or the like (S150A: a metal film forming process).

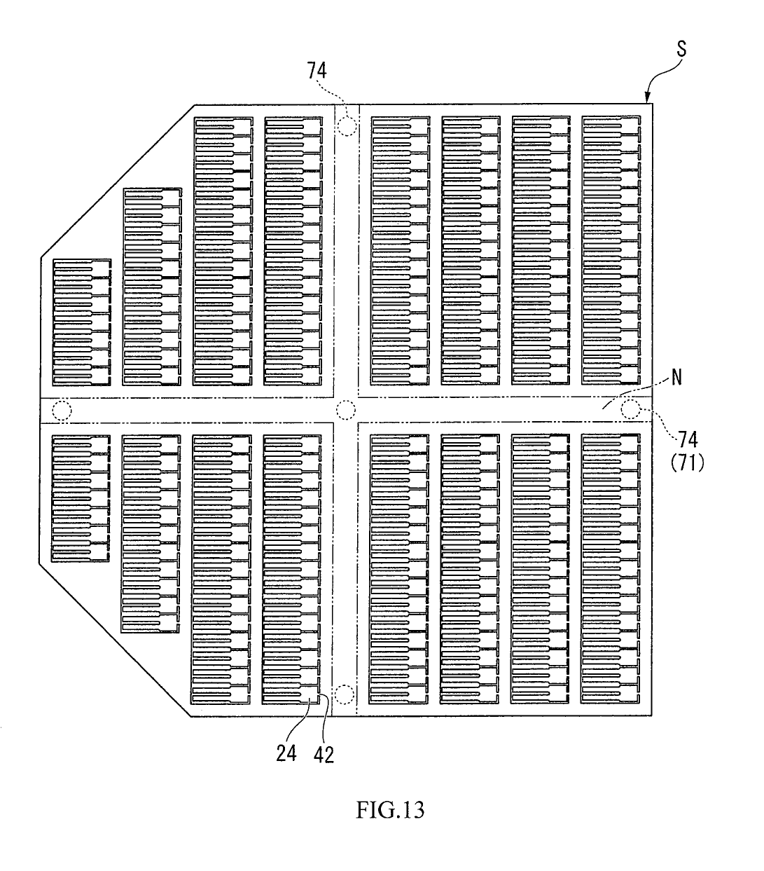

FIGS. 13 and 14 are diagrams for describing a photoresist film forming process, FIG. 13 is a plan view of the wafer, and FIG. 14 is a cross-sectional view corresponding to lines C-C of FIG. 12. In addition, in FIGS. 13 and 14, in order to clarify the drawings, the groove portion 18 mentioned above will be omitted.

Next, as shown in FIGS. 13 and 14, a photoresist film (the mask) 44 is formed on the wafer S formed with the metal film 43 by the use of a photoresist film forming apparatus (a mask forming device) 71 (hereinafter, referred to as a forming apparatus 71) (a photoresist film forming process (a mask forming process): S150B). Hereinafter, firstly, the forming apparatus 71 will be described.

As shown in FIG. 14, the forming apparatus 71 includes a work stage 72 having a flat plate shape on which the wafer S can be set, a sprayer 73 that sprays the photoresist material toward the wafer S set on the work stage 72, and a plurality of spacers (ventilation means) 74 disposed between the work stage 72 and the wafer S.

The sprayer 73 sprays the photoresist material (the mask material) by generating the air flow along the normal direction on the surface of the work stage 72, and includes a spraying nozzle 73a that is opened toward the work stage 72 surface. Furthermore, the sprayer 73 is configured so as to be movable along a plane direction on the work stage 72 surface by a driving device (not shown). In addition, the sprayer 73 may use a commercially available sprayer or the like.

The respective spacers 74 are erected along the normal direction of the work stage 72 surface, and support one surface (a lower surface of FIG. 14) of the wafer S by the upper end surface thereof. Thus, when setting the wafer S on the work stage 72, a gap K of the thickness of the spacer 74 is formed between the wafer S and the work stage 72. Furthermore, the spacer 74 is disposed in a position (for example, a central portion of the non-forming region N and each end portion) overlapping the non-forming region N of the wafer S in the thickness direction on the work stage 72 (see FIG. 12). In addition, in FIG. 13, in order to clarity the description, the spaces 74 are shown at both sides of the piezoelectric plate 24. Furthermore, a heater may be provided in the work stage 72.

In order to perform the photoresist film forming process (S150B) by the use of the forming apparatus 71 configured in this manner, firstly, the wafer S is set on the work stage 72. Specifically, one surface of the wafer S is set in the state of coming into contact with the upper surface of the spacer 74. At this time, by setting the spacer 74 and the non-forming region N of the wafer S so as to overlap each other in the thickness direction of the wafer S, the bending of the wafer S is suppressed, whereby the wafer S can stably be set.

Next, the photoresist material is applied by the spray coat method. Specifically, the photoresist material is gradually sprayed to the wafer S while moving the sprayer 73 by the driving means. As a result, the photoresist material is applied over the whole region of the other surface (the upper surface of FIG. 14) and the side surface of the wafer S.

However, when applying the photoresist material in the state of directly setting the wafer S on the work stage 72 like the related art, the air flow generated from the sprayer 73 collides with the work stage 72 through the opening portion of the wafer S such as between the vibration arm portions 10 and 11 of the piezoelectric plate 24 or between the adjacent piezoelectric plates 24. Then, the air flow collided with the work stage 72 rebounds and stays in the periphery of the opening portion of the wafer S. As a consequence, particularly, in a portion facing the opening portion of the wafer S, the corner of the piezoelectric plate 24 or the like, the photoresist material is hardly dried. For that reason, due to the surface tension of the photoresist material, it is difficult to sufficiently apply the photoresist material in the corner of the piezoelectric plate 24, whereby a region is generated in which the photoresist film is thin or the photoresist film is not formed.

Additionally, there is a possibility that the photoresist material hung and dropped from the wafer S is dried in the state of spanning between the wafer S and the work stage 72, whereby the wafer S and the work stage 72 are attached to each other. In this case, when detaching the wafer S from the work stage 72, since there is a need to tear off the wafer S from the work stage 72, there is a fear that the wafer S may be cracked.

Thus, in the present embodiment, since the gap K is formed between the wafer S and the work stage 72 by the spacer 74, the air permeability of the wafer S in the thickness direction can be improved. That is, after the air flow (an arrow F in FIG. 14) generated upon spraying the photoresist material such as the air flow generated from the sprayer 73, or the air flow drawn and generated by the air flow reaches one surface side of the wafer S through the opening portion of the wafer S such as between the vibration arm portions 10 and 11 of the piezoelectric plate 24 or between the adjacent piezoelectric plates 24, the air flow is distributed through the gap K between the wafer S and the work stage 72. As a result, the photoresist material applied onto the wafer S is easily dried during application. In this case, since the photoresist material is sequentially deposited on the dried photoresist material, the surface tension of the photoresist material in the corner of the piezoelectric plate 24 can be reduced, whereby the photoresist material is easily applied to the corner of the piezoelectric plate 24.

Furthermore, since the wafer S is supported in the state of floating from the work stage 72, the photoresist material is not attached to the wafer S and the work stage 72. As a result, it is possible to prevent the wafer S from being cracked when separating the wafer S from the work stage 72.

After that, by drying the photoresist material, the photoresist film 44 is formed on the piezoelectric plate 24. In addition, after forming the photoresist film 44 from the other surface of the wafer S, when the photoresist film 44 is not formed on one surface side of the wafer S, the wafer S is reversed, and the photoresist film 44 is formed from one surface side of the wafer S by the same method as mentioned above. As a result, the photoresist film 44 can be formed over the whole surface of the wafer S.

Next, a resist pattern forming process (a mask pattern forming process: S150C) is performed in which the photoresist film 44 formed as mentioned above is patterned by the photolithography technique. Specifically, firstly, a photo mask (not shown) is set on the photoresist film 44. The photo mask has an opening portion, for example, in a region other than forming region of the excitation electrodes 13 and 14, the drawing electrodes 19 and 20, and the mount electrodes 16 and 17.

Moreover, ultraviolet rays are irradiated toward the photoresist film 44 via the photo mask. Next, by being immersed in a developer, only the photoresist film 44 of a region (a region covered with the photo mask) is selectively removed to which ultraviolet rays are not exposed. As a result, it is possible to form a resist pattern (the mask pattern) (not shown) on the metal film 43 formed in the metal film forming process (S150A). In the present embodiment, a resist pattern (not shown) is formed in which the photoresist film 44 remains in the region corresponding to the excitation electrodes 13 and 14, the drawing electrodes 19 and 20, and the mount electrodes 16 and 17 of the piezoelectric vibrating reed 4.

Next, an etching process (a coating film pattern forming process: S150D) in which the metal film 43 is etched by the used the resist pattern as the mask, and the respective electrodes (the coating film patterns) 13, 14, 16, 17, 19, and 20 mentioned above are formed. Specifically, the metal film 43 not masked by the resist pattern is selectively removed leaving the metal film 43 masked by the resist pattern. At this time, in the present embodiment, by the photoresist film forming process (S150B) mentioned above, the photoresist film 44 is evenly formed over the whole surface of the piezoelectric plate 24. Thus, in the regions corresponding to the respective electrodes 13, 14, 16, 17, 19, and 20, the resist pattern evenly remains. As a result, since the metal films 43 of the regions corresponding to the respective electrodes 13, 14, 16, 17, 19, and 20 are not etched, it is possible to prevent the disconnection of the respective electrodes 13, 14, 16, 17, 19, and 20.

After that, by removing (S150E) the resist pattern, the electrode forming process (S150) is finished, and the excitation electrodes 13 and 14, the drawing electrodes 19 and 20 and the mount electrodes 16 and 17 are formed on the outer surface of the piezoelectric plate 24.

After the electrode forming process (S150) is finished, a weight metal film 21 formed of the rough adjustment film 21a and the minute adjustment film 21b for the frequency adjustment is formed at the tips of the pair of vibration arm portions 10 and 11 (a weight metal film forming process: S160). In addition, in the present embodiment, a case was described where the excitation electrodes 13 and 14, the drawing electrodes 19 and 20, the mount electrodes 16 and 17, and the weight metal 21 are formed in separate processes, respectively, but the respective electrodes and the weight metal film 21 mentioned above may collectively be formed in the same process.

Next, a rough adjustment process of roughly adjusting the frequency is performed on all the vibration arm portions 10 and 11 formed in the wafer (S170). The process is performed by irradiating the rough adjustment film 21a of the weight metal film 21 with laser light to evaporate a part thereof, and changing the weight. Specifically, firstly, the frequencies of all the vibration arms portions 10 and 11 formed in the wafer are collectively measured, and a trimming amount is calculated depending on a difference between the measured frequency and the predetermined object frequency. After that, based on the calculation result of the trimming amount, the tip of the rough adjustment film 21a of the weight metal film 21 is irradiated with laser light to remove (trim) the rough adjustment film 21a. In addition, a minute adjustment, which further accurately adjusts the resonance frequency, is performed after the mount of the piezoelectric vibrating reed 4.

After the rough adjustment process (S170) is finished, finally, a cutting process is performed which cuts the connection portion 42 connecting the wafer S with the piezoelectric plate 24, separates the plurality of piezoelectric plate 24 from the wafer S to form individual pieces (S180). As a result, it is possible to manufacture a plurality of tuning fork-like piezoelectric vibrating reed 4 from a sheet of wafer S at a time.

At this point of time, the manufacturing process of the piezoelectric vibrating reed 4 is finished, and the piezoelectric vibrating reed 4 shown in FIG. 5 can be obtained.

### (Lead Substrate Wafer Manufacturing Process)

Next, as shown in FIGS. 8 and 10, a lead substrate wafer manufacturing process is performed which manufactures the lead substrate wafer 50 becoming the lead substrate 3 later up to the state of immediately before performing the anodic bonding (S20).

Specifically, after the soda-lime glass is polished up to a predetermined thickness and is cleaned, a disk-like lead substrate wafer 50 is formed in which the damaged layer of the top surface thereof is removed by the etching or the like (S21).

Next, a concave portion forming process is performed which forms a plurality of concave portions 3a for the cavity C on a back 50a (a lower surface in FIG. 6) of the lead substrate wafer 50 in a matrix direction by the etching or the like (S22).

Next, in order to ensure the air permeability between the lead substrate wafer 50 and a base substrate wafer 40 described later, a polishing process (S23) is performed which at least polishes the back 50a side of the lead substrate wafer 50 becoming the bonding surface with the base substrate wafer 40, thereby performing the specular working of the back 50a.

Next, a bonding material forming process (S24) is performed which forms the bonding material 35 on the whole (the bonding surface between the lead substrate wafer 50 and the base substrate wafer 40, and the inner surface of the concave portion 3a) of the back 50a of the lead substrate wafer 50. In this manner, by forming the bonding material 35 on the whole of the back 50a of the lead substrate wafer 50, the patterning of the bonding material 35 is unnecessary, whereby the manufacturing costs can be reduced. In addition, the forming of the bonding material 35 can be performed by the film forming method such as sputtering or a CVD. Furthermore, since the bonding surface is polished before the bonding material forming process (S24), the flatness of the surface of the bonding material 35 is ensured, whereby it is possible to realize the stable bonding with the base substrate wafer 40.

In this manner, the lead substrate wafer manufacturing process (S20) is finished.

### (Base Substrate Wafer Manufacturing Process)

Next, simultaneously with, or before or after the process described above, a base substrate wafer manufacturing process is performed which manufactures the base substrate wafer 40 becoming the base substrate 2 later up to the state of immediately before performing the anodic bonding (S30).

Firstly, after the soda-lime glass is polished up to a predetermined thickness and is cleaned, the disc-like base substrate wafer 40 is formed in which the damaged layer of the top surface thereof is removed by the etching or the like (S31).

Next, a through hole forming process is performed which forms a plurality of through holes 30 and 31 for disposing a pair of penetration electrodes 32 and 33 in the base substrate wafer, for example, by the press working or the like (S32). Specifically, after forming the concave portion from the back 40b of the base substrate wafer 40 by the press working or the like, by performing the polishing at least from the surface 40a side of the base substrate wafer 40, the concave portion is penetrated and the through holes 30 and 31 can be formed.

Next, a penetration electrode forming process (S33) is performed which forms the penetration electrodes 32 and 33 in the through holes 30 and 31 formed in the penetration electrode forming process (S32).

As a result, in the through holes 30 and 31, the core portion 7 is held in the state flush with both surfaces 40a and 40b of the base substrate wafer 40. In this manner, the penetration electrodes 32 and 33 can be formed.

Next, a leading electrode forming process is performed which forms the leading electrodes 36 and 37 formed of the conductive film on the surface 40a of the base substrate wafer 40 (S34). In this manner, the base substrate wafer manufacturing process (S30) is finished.

### (Assembling Process)

Next, the piezoelectric vibrating reed 4 manufactured in the piezoelectric vibrating reed creation process (S10) are mounted on the respective leading electrodes 36 and 37 of the base substrate wafer 40 created by the base substrate wafer creation process (S30) via the bump B such as gold, respectively (a mount process: S40).

Moreover, a superimposition process is performed which superimposes the base substrate wafer 40 created by the creation process of the respective wafers 40 and 50 mentioned above with the lead substrate wafer 50 (a superimposition process: S50). Specifically, both of the wafers 40 and 50 are aligned in a correct position while setting a standard mark (not shown) or the like as an indicator. As a result, the mounted piezoelectric vibrating reed 4 is received in the cavity C that is surrounded by the concave portion 3a formed in the lead substrate wafer 50 and the base substrate wafer 40.

After the superimposition process, a bonding process is performed which applies a predetermined voltage at a predetermined temperature atmosphere to perform the anodic bonding in the state of putting the two superimposed wafers 40 and 50 into an anodic bonding device (not shown) and clamping an outer peripheral portion of the wafer by a holding mechanism (not shown) (S60). Specifically, a predetermined voltage is applied between the bonding material 35 and the lead substrate wafer 50. Then, an electrochemical reaction occurs in an interface between the bonding material 35 and the lead substrate wafer 50, and both of them are firmly brought into close-contact with each other and are anodically bonded to each other. As a result, the piezoelectric vibrating reed 4 can be sealed in the cavity C, whereby it is possible to obtain a wafer bonding body 60 in which the base substrate wafer 40 is bonded to the lead substrate wafer 50.

Moreover, by anodically bonding both of the wafers 40 and 50 like the present embodiment, a time degradation, a deviation due to an impact or the like, a bending state of the wafer bonding body 60 or the like is prevented, whereby both of the wafers 40 and 50 can further firmly be bonded, compared to a case of bonding both of the wafers 40 and 50 by an adhesive or the like.

Moreover, after the anodic bonding mentioned above is finished, an external electrode forming process is performed which patterns the conductive material on the back 40b of the base substrate wafer 40 and forms a plurality of external electrodes 38 and 39 that is electrically connected to the pair of penetration electrodes 32 and 33, respectively (S70). By the process, the piezoelectric vibrating reed 4 sealed in the cavity C can be operated by the use of the external electrodes 38 and 39.

Next, as shown in FIG. 8, a minute adjustment process of minutely adjusting the frequencies of the individual piezoelectric vibrating reeds 4 sealed in the package 5 to enter the range of the object frequency is performed by the use of a trimming device (not shown) (S80). Specifically, the voltage is applied to the external electrodes 38 and 39 to vibrate the piezoelectric vibrating reed 4. Moreover, laser light is irradiated from the outside through the lead substrate wafer 50 while measuring the frequency, thereby evaporating the minute adjustment film 21b of the weight metal film 21. As a result, since the weights of the tip sides of the pair of vibration arm portions 10 and 11 are changed, the frequency of the piezoelectric vibrating reed 4 can be minutely adjusted so as to enter a predetermined range of the nominal frequency.

After the minute adjustment process (S80) is finished, an individual process is performed which cuts the bonded wafer bonding body 60 along the cutting line M to form individual pieces (S90).

Next, an electrical characteristic test of the inner portion of the individualized piezoelectric vibrator 1 is performed (S100).

In the electrical characteristic test (S100), the frequency, the resistance value, the drive level characteristic (an excitation electric power dependence of the frequency and the resistance value) of the piezoelectric vibrating reed 4 or the like are measured and checked. Furthermore, an insulation resistance characteristic, an impact characteristic performed by dropping the piezoelectric vibrator 1 or the like are checked. Moreover, an exterior test of the piezoelectric vibrator 1 is performed, and the size, the quality or the like is finally checked. Thereby, the manufacturing of the piezoelectric vibrator 1 is finished.

In this manner, in the present embodiment, in the photoresist film forming process (S150B), a configuration was adopted in which the photoresist material is applied in the state of setting the wafer S on the work stage 72 via the spacer 74.

According to the configuration, by forming the gap K between the wafer S and the work stage 72, the air permeability of the wafer S in the thickness direction can be improved. That is, as mentioned above, the air flow generated during spraying of the photoresist material is distributed in the gap K between the wafer S and the work stage 72 through the opening portion of the wafer S, the photoresist material applied onto the wafer S is easily dried during application. In this case, since the photoresist material is gradually deposited on the dried photoresist material, the surface tension of the photoresist material in the corner of the piezoelectric plate 24 can be reduced, whereby the photoresist material is easily applied to the corner of the piezoelectric plate 24. Thus, it is possible to evenly form the photoresist film 44 over the whole surface of the piezoelectric plate 24.

As a result, since the resist pattern can evenly be formed in the regions corresponding to the respective electrodes 13, 14, 16, 17, 19, and 20, the metal films 43 of the regions corresponding to the respective electrodes 13, 14, 16, 17, 19, and 20 are not etched in the etching process (S150D). As a consequence, the disconnections of the respective electrodes 13, 14, 16, 17, 19, and 20 are prevented, whereby it is possible to provide the piezoelectric vibrating reed 4 of high quality having no conduction defect and having a low CI value.

In this case, since the spacer 74 is merely interposed between the wafer S and the work stage 72, it is possible to suppress an increase in the number of manufacturing processes, and a drop in manufacturing efficiency.

Furthermore, since the exterior of the piezoelectric plate 24 is also not changed, the vibration characteristic does not fluctuate.

In addition, since the application is performed while drying the photoresist material, separate drying means such as a blower is not used, which can also suppress an increase in manufacturing costs.

Moreover, according to the piezoelectric vibrator 1 of the present embodiment, since the piezoelectric vibrating reed 4 mentioned above is sealed in the package 5, it is possible to provide the piezoelectric vibrator 1 of high quality of excellent characteristic and reliability.

### (Oscillator)

Next, an embodiment according to the present invention will be described with reference to FIG. 15.

As shown in FIG. 15, the oscillator 100 of the present embodiment is configured as a resonator in which the piezoelectric vibrator 1 is electrically connected to an integrated circuit 101. The oscillator 100 includes a substrate 103 with an electronic component 102 such as a condenser mounted thereon. The integrated circuit 101 for the oscillator mentioned above is mounted on the substrate 103, and the piezoelectric vibrating reed 4 of the piezoelectric vibrator 1 is mounted near the integrated circuit 101. The electronic component 102, the integrated circuit 101, and the piezoelectric vibrator 1 are electrically connected by a wiring pattern (not shown). In addition, the respective components are molded by resin (not shown).

In the oscillator 100 configured in this manner, upon applying the voltage to the piezoelectric vibrator 1, the piezoelectric vibrating reed 4 in the piezoelectric vibrator 1 is vibrated. The vibration is converted to the electric signal by the piezoelectric characteristic of the piezoelectric vibrating reed 4 and is input to the integrated circuit 101 as the electric signal. The input electric signal is subjected to various processes by the integrated circuit 101 and is output as the frequency signal. As a result, the piezoelectric vibrator 1 functions as the resonator.

Furthermore, by selectively setting the configuration of the integrated circuit 101, for example, a RTC (real time clock) module or the like depending on demand, it is possible to add a function of controlling an operation date or a time of the device or external device other than a single-function oscillator for the timepiece or the like, or providing a time, a calendar or the like.

As mentioned above, according to the oscillator 100 of the present embodiment, since the piezoelectric vibrator 1 mentioned above is included, it is possible to provide the oscillator 100 of high quality having excellent characteristic and reliability. Furthermore, in addition to this, it is possible to obtain a high precision frequency signal that is stable for a long period of time.

### (Electronic Apparatus)

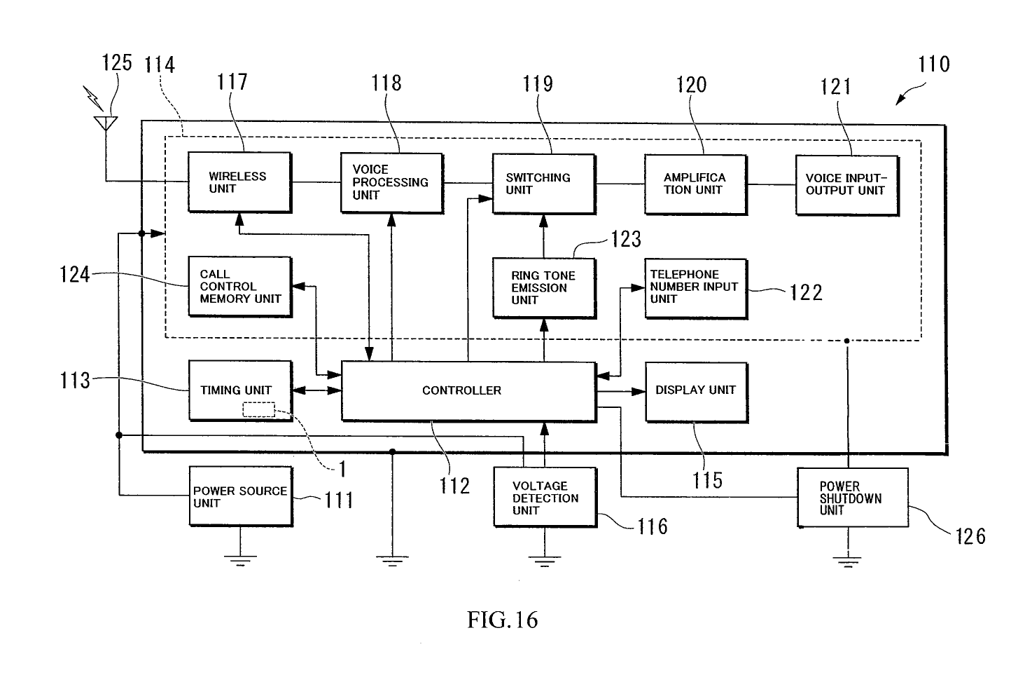

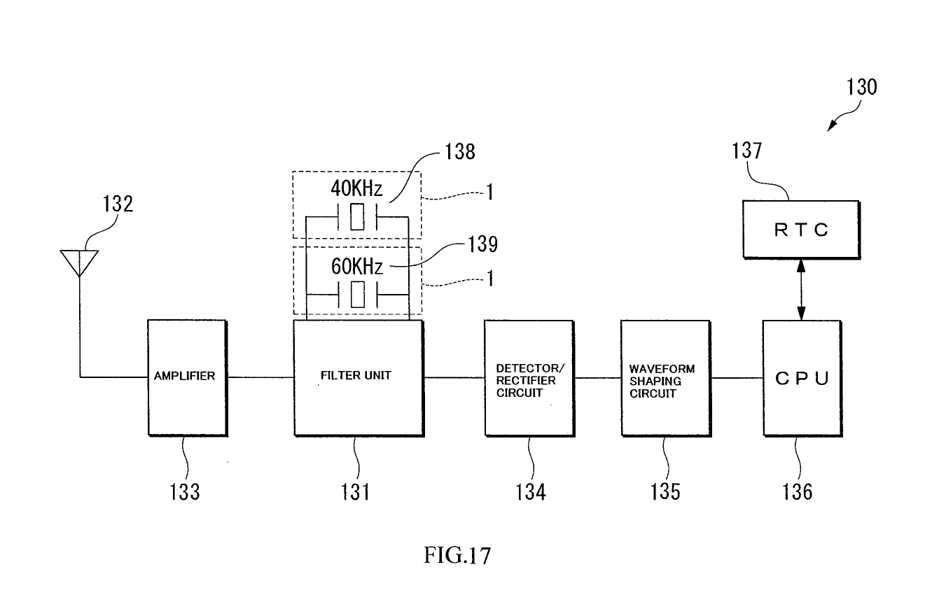

Next, an embodiment of the electronic apparatus according to the present invention will be described with reference to FIG. 16. Furthermore, as the electronic apparatus, a portable information device 110 having the piezoelectric vibrator 1 will be described as an example. Firstly, the portable information device 110 of the present embodiment is represented by, for example, a mobile phone, and is a device that develops and improves a wristwatch in the related art. An exterior thereof is similar to the wristwatch, a liquid crystal display is disposed in a portion corresponding to a text plate, and a current time or the like can be displayed on the screen. Furthermore, in the case of being used as a communicator, the device is removed from the wrist, and the communication like the mobile phone of the related art can be performed by a speaker and a microphone equipped in the inner portion of the band. However, the device is considerably reduced in size and weight compared to the mobile phone of the related art.

### (Portable Information Device)

Next, a configuration of portable information device 110 of the present embodiment will be described. As shown in FIG. 16, the portable information device 110 includes the piezoelectric vibrator 1 and a power source portion 111 for supplying the electric power. For example, the power source portion 111 is formed of a lithium secondary battery. A control portion 112 performing various controls, clock portions 113 performing the count such as the time, a communication portion 114 performing the communication with the outside, a display portion 115 displaying various pieces of information, and a voltage detection portion 116 detecting the voltage of the respective function portions are connected to the power source portion 111 in parallel. Moreover, the electric power is supplied to the respective function portions by the power source portion 111.

The control portion 112 controls the respective function portions, and performs the operation control of the whole system such as reception and the transmission of the sound data, measurement and display of the current time or the like. Furthermore, the control portion 112 includes a ROM with a program written thereon in advance, a CPU reading and executing the program written on the ROM, a RAM used as a work area of the CPU or the like.

The clock portion 113 includes an integrated circuit equipped with an oscillation circuit, a register circuit, a counter circuit, an interface circuit or the like, and the piezoelectric vibrator 1. When applying the voltage to the piezoelectric vibrator 1, the piezoelectric vibrating reed 4 is vibrated, and the vibration is converted into the electric signal by the piezoelectric characteristic of crystal and is input to the oscillation circuit as the electric signal. The output of the oscillation circuit is binarized and is counted by the register circuit and the counter circuit. Moreover, the signal is received and transmitted together with the control portion 112 via the interface circuit, and the current time, the current date, the calendar information or the like are displayed on the display portion 115.

The communication portion 114 has the same function as the mobile phone of the related art, and includes a wireless portion 117, a sound process portion 118, a switching portion 119, an amplification portion 120, a sound input and output portion 121, a phone number input portion 122, a ringtone generating portion 123, and a call control memory portion 124.

The wireless portion 117 exchanges the transmission and the reception of various pieces of data such as the sound data with a base station via an antenna 125. The sound process portion 118 encodes and decodes the sound signal that is input from the wireless portion 117 or the amplification portion 120. The amplification portion 120 amplifies the signal input from the sound process portion 118 or the sound input and output portion 121 up to a predetermined level. The sound input and output portion 121 is constituted by a speaker, a microphone or the like, heightens the ringtone or the received sound or collects the sound.

Furthermore, the ringtone generating portion 123 creates the ringtone depending on the call from the base station. The switching portion 119 switches the amplification portion 120 connected to the sound process portion 118 into the ringtone generating portion 123 only at the time of the reception, whereby the ringtone created in the ringtone generating portion 123 is output to the sound input and output portion 121 via the amplification portion 120.

In addition, the call control memory portion 124 stores the program relating to the call arrival and departure control of the communication. Furthermore, the phone number input portion 122 includes, for example, number keys from 0 to 9, and other keys, and a phone number or the like of a communication target is input by pressing the number keys or the like.

When the voltage added to the respective function portions such as the control portion 112 by the power source portion 111 is lower than a predetermined value, the voltage detection portion 116 detects the voltage drop and notifies the same to the control portion 112. The predetermined voltage value of this time is a value which is set as a minimum voltage required for stably operating the communication portion 114 in advance, and, for example, is about 3 V. The control portion 112 received the notification of the voltage drop from the voltage detection portion 116 prevents the operation of the wireless portion 117, the sound process portion 118, the switching portion 119, and the ringtone generating portion 123. Particularly, the stop of operation of the wireless portion 117 having high power consumption is essential. In addition, an indication is displayed on the display portion 115 in which the communication portion 114 is unusable from the shortage of the battery residual amount.

That is, the operation of the communication portion 114 is prohibited by the voltage detection portion 116 and the control portion 112, and the indication thereof can be displayed on the display portion 115. The display may be a text message, but an x (false) mark may be displayed on a phone icon displayed on the upper portion of the display surface of the display portion 115 as a further intuitive display.

In addition, a power shut-off portion 126 capable of selectively cutting the power source of a portion relating to the function of the communication portion 114 is included, whereby the function of the communication portion 114 can be further reliably stopped.

As mentioned above, according to the portable information device 110 of the present embodiment, since the piezoelectric vibrator 1 mentioned above is included, it is possible to provide the portable information device 110 of high quality having excellent characteristics and reliability. Furthermore, in addition to this, stable and precision timepiece information can be displayed for a long period of time.

### (Radio Timepiece)

Next, an embodiment of a radio timepiece according to the present invention will be described with reference to FIG. 17.

As shown in FIG. 17, the radio timepiece 130 of the present embodiment includes the piezoelectric vibrator 1 electrically connected to a filter portion 131, and is a timepiece that has a function of receiving a standard radio wave including the timepiece information and automatically correcting and displaying the same at a correct time.

In Japan, in Fukushima Prefecture (40 kHz) and Saga Prefecture (60 kHz), transmission stations (transmission departments) transmitting the standard radio wave are present and transmit the standard radio wave, respectively. Long wave such as 40 kHz or 60 kHz combinedly has a nature of being diffused through the surface of the earth and a nature of being diffused while being reflected by an ionization layer and the surface of earth, the diffusion range is wide, and two transmission stations cover all of Japan.

Hereinafter, a functional configuration of the radio timepiece 130 will be specifically described.

The antenna 132 receives the standard radio wave having the long radio wave of 40 kHz or 60 kHz. The standard radio wave of the long radio wave performs an AM modulation of the time information called a time code to the carrier wave of 40 kHz or 60 KHz. The received standard radio wave of the long radio wave is amplified by an amplifier 133, and is filtered and tuned by a filter portion 131 having a plurality of piezoelectric vibrators 1. The piezoelectric vibrators 1 in the present embodiment include crystal vibrator portions 138 and 139 having the same resonance frequency of 40 kHz and 60 kHz as the carrier frequency mentioned above, respectively.

In addition, the filtered signal of a predetermined frequency is detected and demodulated by a detection and rectifier circuit 134. Next, the time code is taken out via a waveform shaping circuit 135 and is counted by the CPU 136. In the CPU 136, information such as a current year, an integration date, a day of week, and a time are read. The read information is reflected on the RTC 137 and the correct time information is displayed.

Since the carrier wave is 40 kHz or 60 kHz, as the crystal vibration portions 138 and 139, a vibrator having the tuning fork-like structure mentioned above is preferable.

In addition, the description mentioned above is indicated as the example of Japan, but the frequency of the standard radio wave of the long radio wave differs abroad. For example, a standard radio wave of 77.5 kHz is used in Germany. Thus, when the radio timepiece 130 capable of responding even abroad is built in the portable device, there is a need for the piezoelectric vibrator 1 having the frequency difference from the case of Japan.

As mentioned above, according to the radio timepiece 130 of the present embodiment, since it includes the piezoelectric vibrator 1, it is possible to provide a radio timepiece 130 of high quality having excellent characteristic and reliability. Furthermore, in addition to this, it is possible to stably and accurately count the time for a long period of time.

In addition, the technical scope of the present invention is not limited to the embodiment mentioned above, and various modifications can be added within the scope not departing from the gist of the present invention.

For example, in the embodiment mentioned above, a configuration was adopted in which the spacer 74 is interposed between the wafer S and the work stage 72 to improve the air permeability. However, a configuration may be adopted in which a vent hole (ventilation means) is formed in the work stage 72 without being limited thereto. In this case, it is preferable that the vent hole be formed in a position that is not superimposed with the piezoelectric plate 24, the connection portion 42, and the non-forming region N when viewed from the thickness direction of the wafer S.

Furthermore, in the embodiment mentioned above, a case was described where the wafer S is set on the flat plate-like work stage 72 one by one to form the photoresist film 44, but a prism-shaped work stage capable of being rotated around a rotation axis may be used without being limited thereto. Specifically, a plurality of sheets of wafer S is set at the respective sides of the work stage, and the photoresist material is sprayed toward the side of the rotating work stage.

According to the configuration, it is possible to collectively form the photoresist film 44 on the plurality of wafers S.

Furthermore, in the embodiment mentioned above, a case was described where the photoresist material is sprayed along the normal direction of the surface of the work stage 72, but the photoresist material may be sprayed from an oblique direction along the normal direction of the surface of the work stage 72.

Furthermore, in the embodiment mentioned above, the present invention was described as an example of the tuning fork-like piezoelectric vibrating reed, but the present invention may be applied to, for example, an AT cut type piezoelectric vibrating reed (a thickness-shear vibrating reed) or the like without being limited thereto.

In addition, in the embodiment mentioned above, the surface mount type piezoelectric vibrator 1 was described as an example, but the present invention can also be applied to a cylinder package type piezoelectric vibrator, without being limited thereto.

In addition, in the embodiment mentioned above, the description is given of the time when forming the electrode on the piezoelectric plate 24, but the present invention is able to be applied to the respective processes such as when forming the exterior of the piezoelectric plate 24, or when forming the groove portion 18 or the like.

What is claimed is:

1. A method of manufacturing a piezoelectric vibrating reed comprising:
a mask forming process of applying a mask material to a coating film formed on a piezoelectric plate to form a mask on the coating film;
a mask pattern forming process of patterning the mask to form a mask pattern; and
a coating film pattern forming process of removing the coating film of a region other than a forming region of the mask pattern to form the coating film pattern,
wherein the mask forming process is performed by the use of a mask forming apparatus that has a sprayer which generates an air flow toward the coating film to spray the mask material, and ventilation means for distributing the air flow to a side opposite to the sprayer with respect to the piezoelectric plate.

2. The method according to claim 1,
wherein, in the mask forming process, the spraying by the sprayer is performed in the state of setting the piezoelectric plate on a work stage disposed at a side opposite to the sprayer with respect to the piezoelectric plate, and
the ventilation means is a spacer that is disposed between the piezoelectric plate and the work stage.

3. The method according to claim 1,
wherein, in the mask forming process, the spraying by the sprayer is performed in the state of setting the piezoelectric plate on the work stage disposed at a side opposite to the sprayer with respect to the piezoelectric plate, and
the ventilation means is a vent hole that is formed so as not to overlap the piezoelectric plate in a thickness direction in the work stage.

4. The method according to claim 1,
wherein the coating film is a conductive metal film that becomes an electrode formed on the piezoelectric plate, and
the mask material is a photoresist material that becomes a mask when forming the electrode.

5. A piezoelectric vibrating reed manufactured by the use of the method of manufacturing the piezoelectric vibrating reed according to claim 1.

6. A piezoelectric vibrator in which the piezoelectric vibrating reed according to claim 5 is sealed in a package in an air-tight manner.

7. An oscillator in which the piezoelectric vibrator according to claim 6 is electrically connected to an integrated circuit as an oscillating element.

8. An electronic apparatus in which the piezoelectric vibrator according to claim 6 is electrically connected to a clock portion.

9. A radio timepiece in which the piezoelectric vibrator according to claim 6 is electrically connected to a filter portion.
